(19) United States
(12) Patent Application Publication
(10) Pub. No.: US 2023/0323523 A1
(43) Pub. Date: Oct. 12, 2023

(54) METHODS AND SYSTEMS FOR FORMING A BLADE OF A SHAVING DEVICE

(71) Applicant: BIC Violex Single Member S.A., Anoixi (GR)

(72) Inventors: Christos PANDIS, Anoixi (GR); Konstantinos MAVROEIDIS, Anoixi (GR); Evangelos GOGOLIDES, Anoixi (GR); Kosmas ELLINAS, Anoixi (GR); Dimitrios DAVAZOGLOU, Anoixi (GR)

(73) Assignee: BIC Violex Single Member S.A., Anoixi (GR)

(21) Appl. No.: 18/043,884

(22) PCT Filed: Aug. 31, 2021
(86) PCT No.: PCT/EP2021/073980

§ 371 Date: Mar. 2, 2023

Related U.S. Application Data
(60) Provisional application No. 63/074,121, filed on Sep. 3, 2020.

(51) Int. Cl. C23C 14/12; B26B 21/60; C23C 14/58; C23C 14/24

(52) U.S. Cl. CPC C23C 14/12; B26B 21/60; C23C 14/5806; C23C 14/243

(57) ABSTRACT

The present disclosure relates to a method of forming a coating on a blade for a shaver, the method comprising: a first step of evaporating a portion of a supply of a lubricating coating material in a negative pressure chamber, wherein the blade is positioned in the negative pressure chamber adjacent to the supply of the lubricating coating material such that the portion of the lubricating coating material evaporates from the supply and coats the blade; a second step, performed after the first step, of sintering the portion of the lubricating coating material coating the blade by heating the blade to a temperature above the melting temperature of the lubricating coating material; and a third step, performed after the second step, of cooling the blade after sintering to a room temperature.

### CROSS-REFERENCE TO RELATED APPLICATIONS

This application is a National Stage Application of the International Application PCT/EP2021/073980, filed on Aug. 31, 2021, now published as WO 2022/049058, and which claims benefit from the U.S. Provisional Patent Application No. 63/074,121, entitled: “METHODS AND SYSTEMS FOR FORMING A BLADE OF A SHAVING DEVICE”, filed on Sep. 3, 2020, its content being incorporated herein by reference.

### TECHNICAL FIELD

Various aspects of the present disclosure relate to methods and systems for forming a blade for a shaving device. More particularly, the present disclosure describes embodiments of systems and methods for depositing a lubricating material on an edge of a blade for a shaving device, for example, by thermal evaporation. The present disclosure may apply to a manual shaver, and may also apply to an electric shaver, for example, a wet electric shaver.

### BACKGROUND

Razor blades in a shaver are unique cutting tools due to their unique function, among cutting tools, of cutting hair sticking out from the skin. Such cutting action is different from the one of other cutting tools, which requires razor blades to be designed with some specific functionalities.

Many shavers include one or more razor blade(s) with a polymer coating on a portion of the blade, for example, a razor blade edge. The coating, which may be formed of polytetrafluoroethylene (“PTFE”), often helps to lubricate the shaver, for example, helping to minimize the force needed to cut hair and/or helping to reduce friction between the blade(s) and the user's face. The coating is often deposited on the razor blade, for example, via sublimation, electrophoresis, spraying, or dipping. In one embodiment, the coating is applied by spraying coating, which involves PTFE nanoparticles being dispersed in water to form a stable aqueous dispersion. The aqueous dispersion is then spayed on the edges of the blades. However, spray coating often leads the thickness not being uniform, which may be detrimental to shaving performance.

Other methods may apply thin and uniform films PTFE on blade edges. For example, plasma polymerization, chemical vapor deposition, or physical vapor deposition by high frequency magnetron sputtering may be used to apply PTFE. However, while these techniques could lead to thin PTFE films on blade edge, the structure of the film is not the desirable. A film produced by these mechanisms often has a high hardness, for example, due to crosslinking, which may lead to a greater coefficient of friction compared to bulk-like PTFE. As mentioned above, greater friction is not desirable for shaving.

Accordingly, existing coating processes often yield a coating on the razor blade that does not have a uniform thickness, that has an undesirable hardness (e.g., due to cross-linking) which may increase the friction between the razor blade and the skin, and/or that may otherwise not be desirable for a shaver.

The background description provided herein is for the purpose of generally presenting the context of the disclosure. Unless otherwise indicated herein, the materials described in this section are not prior art to the claims in this application and are not admitted to being prior art, or suggestions of the prior art, by inclusion in this section.

### SUMMARY

Aspects of the disclosure include:

A method of forming a coating on a blade for a shaver, the method comprising: a first step of evaporating a portion of a supply of a lubricating coating material in a negative pressure chamber, wherein the blade is positioned in the negative pressure chamber adjacent to the supply of the lubricating coating material such that the portion of the lubricating coating material evaporates from the supply and coats the blade; a second step, performed after the first step, of sintering the portion of the lubricating coating material coating the blade by heating the blade to a temperature above the melting temperature of the lubricating coating material; and a third step, performed after the second step, of cooling the blade after sintering to a room temperature.

### BRIEF DESCRIPTION OF THE DRAWINGS

The accompanying drawings, which are incorporated in and constitute a part of this specification, illustrate various exemplary embodiments and, together with the description, serve to explain the principles of the disclosure. There are many aspects and embodiments described herein. Those of ordinary skill in the art will readily recognize that the features of a particular aspect or embodiment may be used in conjunction with the features of any or all of the other aspects or embodiments described in this disclosure. Embodiments of the present disclosure will now be described, by way of example only, with reference to the accompanying drawings in which:

FIG. 1 illustrates an exemplary shaver, according to one aspect of the present disclosure.

FIG. 2 is a flow diagram of an exemplary method for coating one or more razor blades for a shaver, according to aspects of the present disclosure.

FIG. 3 illustrates a schematic representation of an exemplary system for coating one or more razor blades for a shaver, according to aspects of the present disclosure.

FIG. 4 is an image of a coated razor blade for a shaver, according to aspects of the present disclosure.

FIG. 5 is an image of another coated razor blade for a shaver, according to aspects of the present disclosure.

FIGS. 6A and 6B are images of another coated razor blade, according to aspects of the present disclosure.

FIG. 7 illustrates relevant data obtained from an analysis of coated razor blades, according to aspects of the present disclosure.

FIGS. 8A and 8B are images of another coated razor blade at different magnifications, according to aspects of the present disclosure.

FIG. 9A is image of a coated razor blade after spraying an aqueous solution of PTFE nanoparticles and the resulting thickness data for the coating on a razor blade.

FIG. 9B is image of a coated razor blade according to aspects of the present disclosure and the resulting thickness data for the coating on a razor blade.

FIG. 10. Coefficient of friction diagram for the low and high molecular weight PTFE after evaporation and for the sprayed low molecular weight PTFE.

### DETAILED DESCRIPTION

The present disclosure relates to methods and systems for coating one or more razor blades for use in a shaver, particularly for coating the one or more razor blades with a lubricating coating.

Both the foregoing general description and the following detailed description are exemplary and explanatory only and are not restrictive of the features, as claimed. As used herein, the terms “comprises,” “comprising,” or other variations thereof, are intended to cover a non-exclusive inclusion such that a process, method, article, or apparatus that comprises a list of elements does not include only those elements, but may include other elements not expressly listed or inherent to such a process, method, article, or apparatus. Additionally, the term “exemplary” is used herein in the sense of “example,” rather than “ideal.” It should be noted that all numeric values disclosed or claimed herein (including all disclosed values, limits, and ranges) may have a variation of +/−10% (unless a different variation is specified) from the disclosed numeric value. Moreover, in the claims, values, limits, and/or ranges means the value, limit, and/or range+/−10%. Furthermore, the terms “about” or “approximately” are defined herein as encompassing a variation of +/−10% from the disclosed numeric value (unless a different variation is specified).

Embodiments of the present disclosure related to methods and systems for forming one or more blades for a shaver. The methods and systems disclosed herein may help to form one or more blades with a coating of a lubricating material. The methods and systems disclosed herein may help to form a thin and uniform coating of the lubricating material on the one or more blades. In at least some embodiments, the present disclosure can result in (1) a thin lubricating coating achieved in lower pressure conditions and under a less complex thinning process, for example compared to a process using a solvent, and (2) a thin coating that is suitable for blades used in shaving contributing enhanced shaving performance, where this coating is achieved after applying sintering and cooling steps that optimize the coating properties. Consistent with this, in at least some embodiments, no solvent is used in the manufacturing process. For example, the resulting coating on a razor blade may be a coating of fluoro-containing polymer that is thin and uniform, and that has the same or similar properties as bulk-like properties of the fluoro-containing polymer. An exemplary method may include thermal evaporation of fluoro-containing polymer powder conducted in a vacuum or negative pressure chamber and induced by a power supply that applies voltage at the evaporation temperature of the fluoro-containing polymer on a boat comprising the fluoro-containing polymer powder; and sintering of the blades bearing the evaporated fluoro-containing polymer at temperature above the melting point of the fluoro-containing polymer and subsequent cooling to room temperature with a controlled cooling rate. The sintering means in particular the heating of the deposited polymeric substance, for example particles, at a specific temperature, higher than the melting temperature, for a specific time to allow the film formation and good adhesion onto the razor blade. More specifically, the step of sintering does not include pressure implementation. For example, for PTFE as fluoro-polymer the sintering is related with the melting point of PTFE that ranges from approximately 323 to approximately 327 degrees Celsius and is dependent on the molecular weight. In other words, the step following the aforementioned step of thermal evaporation of fluoro-containing polymer powder is a heating step named “sintering”, where the fluoro-containing polymer undergoes heating at a specific temperature higher than the melting temperature, more specifically while no pressure is applied. According to an embodiment, the sintering occurs in 1-40 degrees Celsius above the melting temperature, more specifically in 10-30 degrees Celsius above the melting temperature.

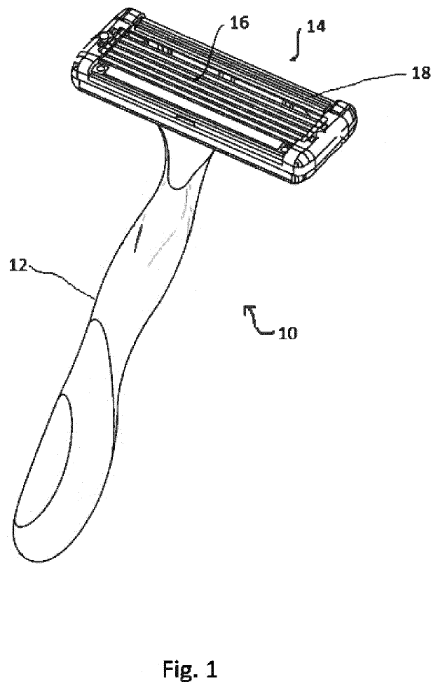

FIG. 1 illustrates an exemplary shaver 10. Shaver 10 includes a handle 12 and a razor cartridge 14 having one or more razor blades 16. Razor cartridge 14 may be releasably secured to handle 12. In one aspect, razor cartridge 14 may include one, two, three, four, five, or more blades 16. Blades 16 may be positioned within razor cartridge 14 such that blades 16 extend generally parallel to one another. As discussed in detail below, blades 16 include a lubricating coating. In some embodiments, the lubricating coating may be a polymeric material, more specifically a non-metallic polymeric material. In some embodiments, the lubricating coating may be formed of a fluoro-containing polymer. In some aspects, the lubricating coating may be any fluoropolymer or fluoro-containing polymer, for example, polymers comprising carbon chains combined with fluorine substituents resulted in [CF2-CF2] repeated groups. Examples of fluoropolymer/fluoro-containing polymers include polytetrafluoroethylene (PTFE), fluorinated ethylene propylene (FEP), perfluoroalkoxy alkane (PFA), etc. In embodiments, PTFE of various molecular weights (MWs) is used for coating purposes. Specifically, PTFE having MWs between 10000 to 10000000 is used which results in a more uniform coating compared to PTFE of higher MWs. Additionally, razor cartridge 14 may include a lubricant strip 18, for example, formed of a composition comprising water-soluble and water-insoluble ingredients, which may help to lubricate skin during a shaving stroke, for example, when lubricant strip 18 is wet. Although not shown, razor cartridge 14 may also include one or more additional blades, for example, positioned on a distal end of razor cartridge 14 opposite to blades 16, and the additional blade(s) may be used for more precise shaving.

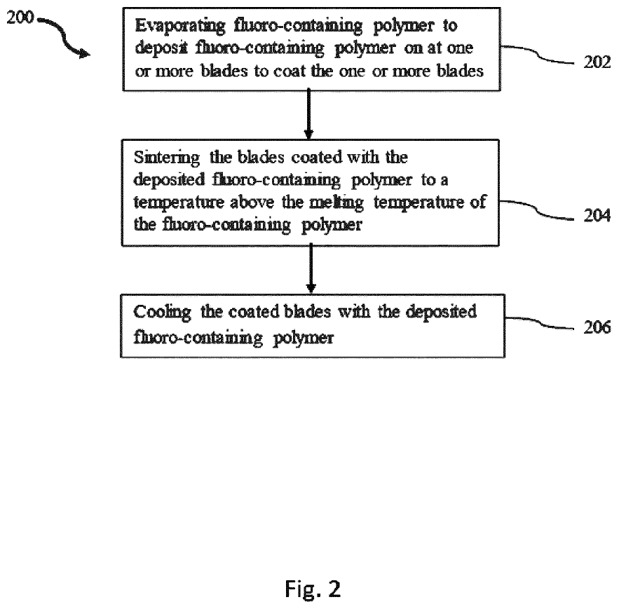

FIG. 2 is a flowchart illustrating a method 200 of depositing a fluoro-containing polymer coating on blades 16, according to aspects of the present disclosure. Method 200 includes a step 202 that includes evaporating the fluoro-containing polymer, for example, in order to deposit evaporated fluoro-containing polymer on at least a portion of blades 16 to coat the blades. Method 200 also includes a post-treatment process that occurs after the evaporating step 202, which includes heating in a step 204 and cooling in a step 206. Step 204 includes sintering blades 16 coated with the deposited fluoro-containing polymer to a temperature above the melting point of the fluoro-containing polymer. Moreover, step 206, which occurs after step 204, includes cooling coated blades 16 with the deposited fluoro-containing polymer. Although method 200 is discussed as being performed with a plurality of blades 16, method 200 may be performed with a single blade 16 or any number of blades 16.

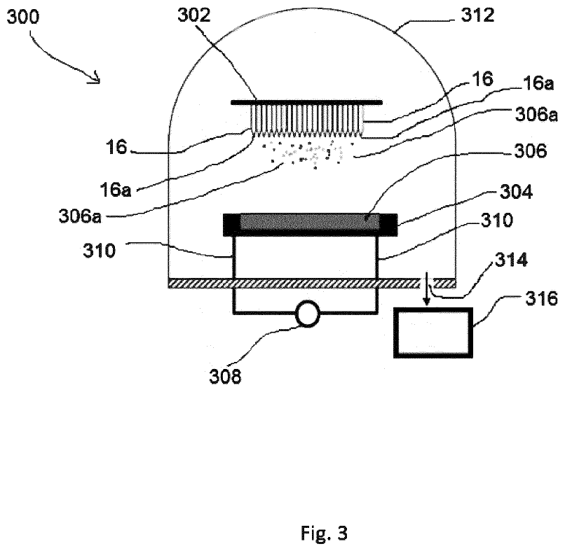

In step 202, blades 16 may be placed under a vacuum or a negative pressure, for example, at a pressure between approximately 10-1 torr and approximately 10-6 torr, in a negative pressure chamber with a powdered supply of fluoro-containing polymer. The time necessary to reach the desired pressure may depend on the volume of the negative pressure chamber, size and/or specifications of the vacuum pump, etc. The supply of fluoro-containing polymer may be heated such that at least some of the supply of fluoro-containing polymer evaporates. For example, as discussed in greater detail with respect to FIG. 3, the supply of fluoro-containing polymer may be contained in a boat, and the boat may heat the supply of fluoro-containing polymer via a voltage being applied to the boat. For example, the boat may be heated to a temperature of approximately 200 degrees Celsius to approximately 400 degrees Celsius, for example, approximately 330 degrees to approximately 380 degrees Celsius. The evaporation may be performed for approximately 5 to approximately 30 minutes, for example, for approximately 15 to approximately 20 minutes. The duration of the evaporation may depend on the amount (e.g., mass) of the fluoro-containing polymer used for the deposition, the negative pressure, the spacing between the fluoro-containing polymer and blades 16, the desired thickness of the fluoro-containing polymer coating, the heating temperature of the boat, etc.

As discussed below, a plurality of blades 16 may be stacked or otherwise arranged on a blade holder. The blade holder may be positioned above or otherwise spaced away from the supply of fluoro-containing polymer such that cutting edges of blades 16 are spaced away from the supply of fluoro-containing polymer. The evaporated fluoro-containing polymer may condense or otherwise accumulate on blades 16, for example, on the cutting edges of blades 16. Accordingly, although not shown, method 200 may include an initial step of positioning blades 16 on the blade holder, and positioning the blade holder within the negative pressure chamber. Moreover, the supply of fluoro-containing polymer, the voltage applied to the boat, the spacing between the supply of fluoro-containing polymer and the blade holder, and other aspects of step 202 may be modified and/or adjusted depending on the size or number of blades 16, the spacing between the supply of fluoro-containing polymer and blades 16, the time duration of step 202, etc.

Step 204 includes sintering blades 16 coated with the deposited PTFE to a temperature above the melting temperature of the fluoro-containing polymer. Heating may occur above the melting point of the polymer to form a continuous film that is well adhered to the blades. For example, step 204 may include placing blades 16 into a furnace, for example, by placing the blade holder in a furnace. In some aspects, the furnace may be a conveyor furnace. In step 204, the furnace may heat blades 16 and the fluoro-containing polymer to a temperature near or above the melting temperature of fluoro-containing polymer (e.g., from approximately 200 degrees Celsius to approximately 400 degrees Celsius, at or above approximately 300 degrees Celsius, from approximately 330 degrees Celsius to approximately 380 degrees Celsius, at or above approximately 330 degrees Celsius, or at or above approximately 360 degrees Celsius). The furnace may heat blades 16 and the fluoro-containing polymer incrementally or otherwise at a controlled rate. For example, the furnace may heat blades 16 from the initial room temperature (e.g., approximately 20-30 degrees Celsius) to an intermediate temperature from approximately 200 degrees Celsius to approximately 300 degrees Celsius at a rate of from approximately 40 degrees Celsius per minute to approximately 60 degrees Celsius per minute. Then, the furnace may heat blades 16 from the intermediate temperature to a maximum temperature (e.g., from approximately 330 degrees Celsius to approximately 360 degrees Celsius) at a rate of approximately 5 degrees Celsius per minute to approximately 20 degrees Celsius per minute, for example, approximately 10 degrees Celsius per minute.

The furnace may hold blades 16 at the maximum temperature for a period of time (e.g., approximately 1 minute, approximately 2 minutes, approximately 3 minutes, etc., or shorter or longer). Alternatively, the furnace may not hold blades 16 at the maximum temperature, but instead may proceed to step 206. In these aspects, the duration of step 204 may be from approximately 5 minutes to approximately 30 minutes, for example, between approximately 6 minutes and approximately 15 minutes, with the duration of step 204 depending on, for example, the heating rate and the maximum temperature.

Step 206 may occur after step 204 and includes cooling blades 16 coated with the deposited fluoro-containing polymer. Step 206 may be performed in the furnace or another container/area which is configured to control the internal temperature. For example, step 206 may include cooling blades 16 and the deposited fluoro-containing polymer from the sintering temperature to the room temperature. Step 206 may be performed in a hot/cold stage furnace.

Alternatively or additionally, step 206 may include delivering nitrogen atmosphere, for example, to the furnace (e.g., a sintering furnace). Moreover, blades 16 may be positioned on a conveyor within the furnace (e.g., the sintering furnace), and step 206 may include controlling a speed of the conveyor within the furnace.

The cooling may be performed incrementally or otherwise at a controlled rate. For example, step 206 may include cooling from the maximum temperature to the intermediate temperature, for example, a temperature of from approximately 200 degrees Celsius to approximately 300 degrees Celsius, at a rate of between approximately 2 degrees Celsius per minute and approximately 10 degrees Celsius per minute, for example, approximately 5 degrees Celsius per minute. The cooling from the maximum temperature to the intermediate temperature may last from approximately 5 minutes to approximately 30 minutes, and the duration of the cooling from the maximum temperature to the intermediate temperature depends on one or more of the maximum temperature, the intermediate temperature, and/or the cooling rate. Then, step 206 may include cooling from the intermediate temperature (e.g., from approximately 200 degrees Celsius to approximately 300 degrees Celsius) to the room temperature at a rate of approximately 30 degrees per minute, or at a rate of at least 30 degrees per minute (e.g., approximately 40 degrees per minutes, approximately 50 degrees per minute, etc.). In one aspect, step 206 may include cooling from the intermediate temperature to the room temperature at a rate of from approximately 20 degrees Celsius per minute to approximately 40 degrees Celsius per minute. In these aspects, the duration of step 206 may be from approximately 10 to approximately 45 minutes, for example, from approximately 10 to approximately 15 minutes, with the duration of step 206 depending on, for example, the maximum temperature, the intermediate temperature, the room temperature, and/or the cooling rates.

FIG. 3 illustrates a schematic representation of an exemplary system 300 that may be used to coat one or more blades 16, for example, via method 200. System 300 includes one or more blades 16 coupled to a blade holder 302, for example, a plurality of blades 16 may be stacked or otherwise arranged on blade holder 302. System 300 may also include a holder or a boat 304 with a supply of fluoro-containing polymer 306, for example, approximately 50 mg to approximately 500 mg, for example, approximately 150 mg to approximately 250 mg, or approximately 200 mg of fluoro-containing polymer. The supply of fluoro-containing polymer 306 may initially be in a solid (e.g., powder form), but may transition to a liquid and/or gaseous state to form vapor PTFE 306a when heated. The supply of fluoro-containing polymer 306 may include grades of fluoro-containing polymer, including, for example, a special grade (LW 2120) of PTFE nanoparticles, which may also be used for spray coating. Boat 304 may be at least partially metallic, for example, at least partially formed of tungsten, molybdenum, tantalum, stainless steel, etc. The supply of fluoro-containing polymer 306 may be spaced away from blades 16, for example, from blade edges 16a, by approximately 3 cm to approximately 10 cm, for example, approximately 4 cm to approximately 7 cm.

As shown, the sharp or cutting edges 16a of blades 16 may face the supply of PTFE 306 (and may be disposed closer to the supply of fluoro-containing polymer 306 than respective ends of blade 16 that are directly coupled to blade holder 302). In one aspect, boat 304 is electrically connected to a power source 308 via one or more wires or cables 310, and power source 308 may control the temperature of boat 304, for example, to help evaporate solid fluoro-containing polymer 306 to form vapor fluoro-containing polymer 306a. Blade holder 302, blades 16, boat 304, and PTFE 306 may be enclosed in a vacuum or negative pressure chamber 312, for example, with a port 314 fluidly coupled to a vacuum (or negative pressure) pump 316, which may be a mechanical vacuum pump. As shown, power source 308 may be outside/exterior of negative pressure chamber 312, but electrically connected to boat 304 via the one or more cables or wires 310.

As discussed above with respect to FIG. 2, vacuum pump 316 may be activated to create an at least partial vacuum in negative pressure chamber 312, for example, under a pressure of approximately 10-1 torr to approximately 10-6 torr. Power source 308 may also be activated by applying a voltage in order to heat the boat 304 from approximately 200 degrees Celsius to 400 degrees Celsius for example approximately 330 degrees Celsius to approximately 380 degrees Celsius. As boat 304 heats up, fluoro-containing polymer 306 may begin to evaporate and form fluoro-containing polymer vapor 306a. Then, as shown in FIG. 3, fluoro-containing polymer vapor 306a may percolate within negative pressure chamber 312 and may condense or otherwise be deposited on blades 16, for example, at least on cutting edges 16a. As mentioned above, the evaporation may be performed for approximately 5 minutes to approximately 30 minutes, for example, for approximately 15 minutes to approximately 20 minutes.

Additionally, although not shown, negative pressure chamber 312 may include a heating source, for example, an infrared heating source or another similar heating mechanism. In this aspect, the steps of method 200 may be performed in negative pressure chamber 312 with the heating source. For example, in this aspect, the evaporation of step 202, along with the heating and cooling of steps 204 and 206, may be performed in the negative pressure chamber with heating. Additionally, in some aspects, cooling step 206 may include the introduction of a cooling source, for example, nitrogen atmosphere.

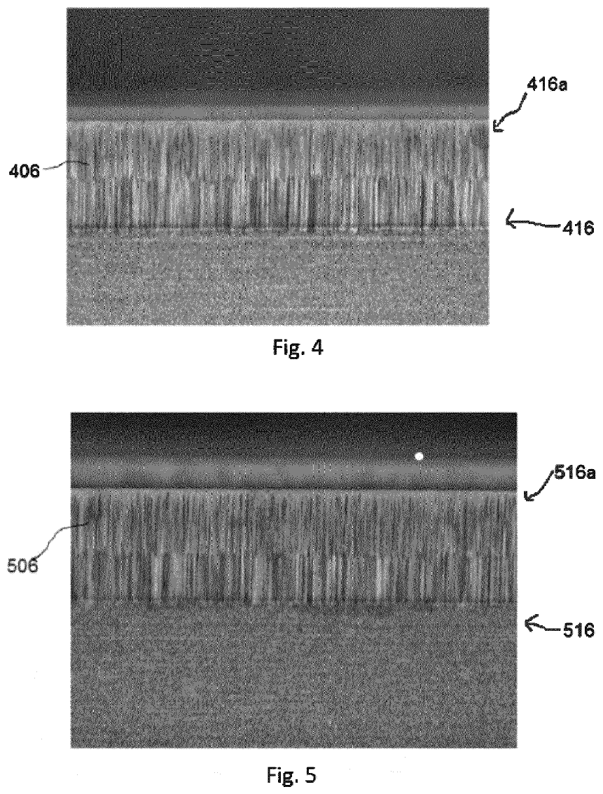

FIG. 4 illustrates one exemplary blade 416 coated with PTFE and sintered, and FIG. 5 illustrates another exemplary blade 516 coated with PTFE and sintered. In particular, FIG. 4 illustrates an optical microscopy image (e.g., at 100 times magnification) of a portion of blade 416 with a PTFE coating 406 on cutting edge 416a after method 200. In the embodiment shown in FIG. 4, step 202 was performed with 150 mg of PTFE, and boat 304 heating temperature from approximately 200 degrees Celsius to 400 degrees Celsius for example approximately 330 degrees Celsius to approximately 380 degrees Celsius. Additionally, blade holder 302 was positioned such that blade edge 416a was positioned 7 cm away from the supply of PTFE 306. Then, the sintering of step 204 was performed to heat blade 416 to a maximum temperature of 330 degrees Celsius. After the sintering, the cooling in step 206 was performed at a rate of 5 degrees Celsius per minute to an intermediate temperature and at a rate of 40 degrees Celsius per minute from the intermediate temperature to room temperature.

FIG. 5 illustrates an optical microscopy image (e.g., at 100 times magnification) of a portion of blade 516 with PTFE coating 506 on cutting edge 516a after method 200. In the embodiment shown in FIG. 5, step 202 was performed with 250 mg of PTFE, and boat 304 was heated to a temperature of approximately 200 degrees Celsius to approximately 400 degrees Celsius, for example, approximately 330 degrees Celsius to approximately 380 degrees Celsius. Additionally, blade holder 302 was positioned such that blade edge 516a was positioned 7 cm away from the supply of PTFE 306. Then, the sintering step of 204 was performed to heat blade 516 to a maximum temperature of 360 degrees Celsius. After the sintering, the cooling in step 206 was performed at a rate of 5 degrees Celsius per minute to an intermediate temperature, and then at a rate of 40 degrees Celsius per minute from the intermediate temperature to room temperature. Based on a comparison of blade 416 and blade 516, the higher maximum sintering temperature yields a thinner coating of PTFE compared to a lower maximum temperature.

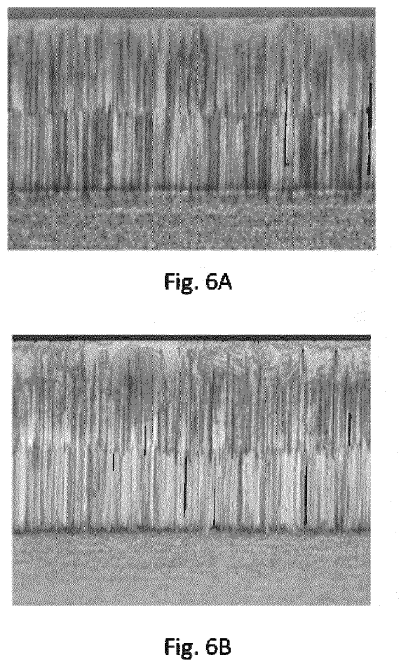

FIGS. 6A and 6B illustrate optical microscopy images (e.g., at 200 times magnification) of additional blade coated with PTFE and sintered at a maximum temperature of 330 degrees Celsius with different cooling rates. Based on a comparison of blade shown in FIG. 6A and the blade shown in FIG. 6B, the slower cooling rate (e.g., approximately 2 degrees Celsius per minute to approximately 5 degrees Celsius per minute) at least during the cooling from the maximum temperature to an intermediate temperature of approximately 300 degrees Celsius yields a more homogenous coating of PTFE compared to a more rapid cooling rate (e.g., approximately 10 to approximately 50 degrees Celsius per minute) from the maximum temperature to the intermediate temperature.

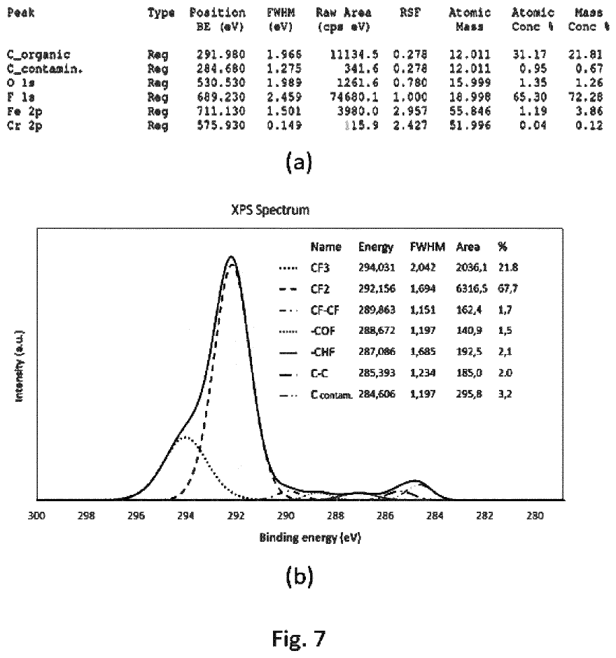

FIG. 7 illustrates a quantification report of various properties of the PTFE film deposited using evaporation and thermal annealing, for example, via X-ray photoelectron spectroscopy (XPS) analysis. XPS analysis revealed that all PTFE coatings exhibited a fluorine to carbon (“F/C”) ratio close to 2, for example, greater than about 1.5, (i.e., similar to bulk PTFE). In some aspects, the blade may include a coating having a F/C ratio that is greater than approximately 1.7. The F/C ratio in bulk (pure) PTFE is 2, which explains that a F/C ratio close to 2 entails a coating having similar properties with bulk PTFE, as desired for a blade coating having improved lubricating properties. As the F/C ratio decreases, the resulting coating departs from a bulk PTFE and lacks the bulk-like properties of PTFE. Thus, blades bearing coatings having low F/C ratio lead to discomfort shaving. Additionally, in some aspects, after cooling, the blade may include a coating having a CF2 content greater than approximately 60%. For example, the fluorine mass concentration of the PTFE coatings was higher than 70% in all cases studied. In some embodiments, the blade may include a coating having a CF2 content 100%. The CF2 content in bulk (pure) PTFE is 100%, which explains that CF2 content close to 100% entails a coating having similar properties with bulk PTFE as desired for a blade coating having improved lubricating properties. As the CF2 content is reduced, the resulted coating departs from a bulk PTFE and lacks the bulk-like properties of PTFE. The presence of CF2 in small quantity indicates increased crosslinking, which is undesirable because it stiffens the coating structure and deteriorates the lubricating properties. Thus, blades bearing coatings having low CF2 content lead to discomfort shaving. FIG. 7 illustrates the XPS analysis of films deposited on blades 16 using PTFE evaporation under the following conditions: evaporation temperature approximately 340 degrees Celsius to approximately 360 degrees Celsius, PTFE mass: 50 mg, chamber pressure: from approximately 10-1 torr to approximately 10-2 torr, distance between supply of PTFE and blade (e.g., from a top of the supply of PTFE to blade edge 16a): 4 cm. Similar results were obtained indicating that the PTFE was not decomposed for evaporation temperature up to 400 degrees Celsius. Furthermore, FIG. 7 illustrates a high resolution analysis of the carbon peaks (or “C peaks”) for an exemplary blade coated with PTFE via method 200, for example, the blade in FIG. 6B, which reveals that the coating consisted of 68% CF2 and 22% of CF3, while the content of the crosslinking species was extremely low. Thus, the deposited PTFE film exhibited properties similar to bulk PTFE.

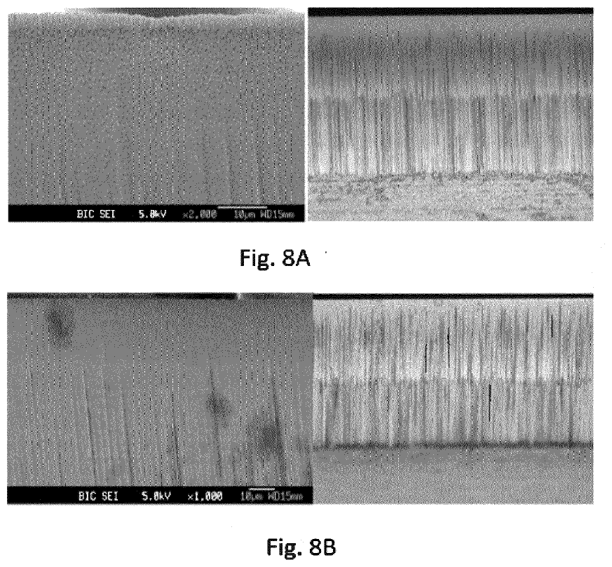

FIGS. 8A and 8B are scanning electron and optical microscope images of the PTFE film deposited on exemplary blades using PTFE evaporation, for example, in step 202, under the following conditions: evaporation temperature approximately 340 degrees Celsius to approximately 360 degrees Celsius, PTFE mass: 250 mg, chamber pressure: from approximately 10-1 torr to approximately 10-2 torr, distance between PTFE and blade: 7 cm. The blades shown in FIG. 8A are blades after the evaporation step 202 and the blades shown in FIG. 8B are images of the blades after the sintering step 204 and cooling step 206, as discussed herein. The optical microscope images of the blade edge are at a magnification of approximately 200 times, and the scanning electron microscope images in FIG. 8A are at a magnification of 2000 times and in FIG. 8B at magnification of 1000 times.

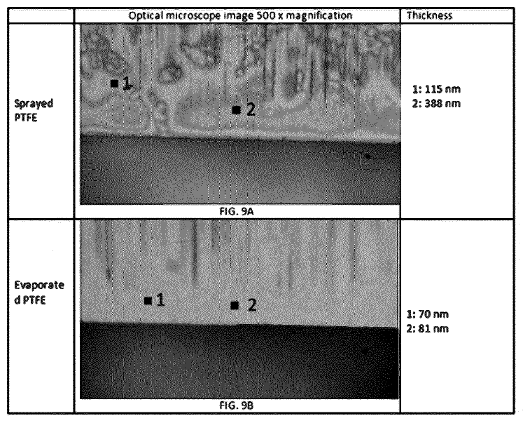

As shown in FIGS. 9A and 9B, the thickness of PTFE may be measured by optical reflectometry on blade 416. For example, FIG. 9A indicates two locations on the blade after spraying an aqueous solution of PTFE and sintering in which the coating thickness was measured. In FIG. 9B, indicates two locations on another blade coated according to aspects of the present disclosure and the thickness of the PTFE coating. The measurements indicate that the thickness of the PTFE coating deposited according to aspects of the present disclosure is less than 100 nm and it is more homogeneous/uniform compared to the coating after spraying an aqueous solution of PTFE and sintering. In some aspects, the thickness of PTFE coating 406 on blade shown in FIG. 9B may be between approximately 10 nm and approximately 400 nm, for example, between approximately 20 nm and approximately 100 nm.

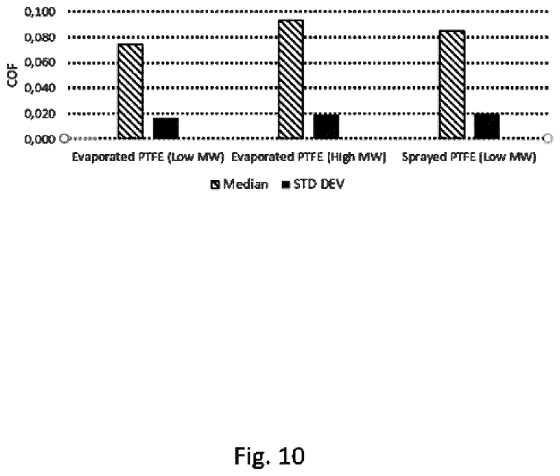

FIG. 10 shows the coefficient of friction (COF) measurements of low (<100.000) and high (1.000.000-10.000.000) molecular weight (MW) evaporated PTFE films, as well as the COF from the sprayed low molecular weight (<100.000) PTFE film on flat Si substrates. The measurements were performed using a tribometer with a carbide ball as probe, speed: 0.8 mm/s, load 100 g after 15 forward passes & 15 back passes of 10 mm each (total 300 mm). The results indicate that the lowest COF (0.074) was recorded for the evaporated low molecular weight PTFE, whereas the high molecular weight PTFE exhibited slightly higher COF (0.094) compared to the sprayed low molecular weight PTFE (0.084). The evaporation step 202 was performed with 150 mg of PTFE, and boat 304 heating temperature from approximately 200 degrees Celsius to 400 degrees Celsius for example approximately 330 degrees Celsius to approximately 380 degrees Celsius. Additionally, blade holder 302 was positioned such that blade edge 416a was positioned 7 cm away from the supply of PTFE 306. Then, the sintering of step 204 was performed to heat blade 416 to a maximum temperature of 330 degrees Celsius. After the sintering, the cooling step 206 was performed at a rate of 5 degrees Celsius per minute to 200 degrees Celcius and at a rate of 40 degrees Celsius per minute from 200 degrees Celcius to room temperature.

The systems and methods discussed herein may be scalable and may be used for mass production, for example, for forming a large number of blades 16, each of which are coated in fluoro-containing polymer. For example, step 202 may be performed as a batch process in a vacuum or negative pressure chamber with a mechanical vacuum pump, a power source to heat the boat and multiple blade holders 302 may hold a plurality of blades 16 (e.g., blades 16 may be stacked). Blade holders consisting of plurality of blades may be mounted on a rotating rack and may be rotated during evaporation step for achieving a more uniform coating. One or more boats 304 may contain sufficient fluoro-containing polymer 306 to coat all of the plurality of blades 16. The boat and the rotating rack of the blade holders may be enclosed in the vacuum or negative pressure chamber. In another aspect, a single boat 306 may contain sufficient fluoro-containing polymer 306 to coat all of the plurality of blades 16 and may be placed either in the middle of the vacuum chamber or multiple boats may be used in parallel inside the same chamber. Additionally, step 204 and/or step 206 may be performed in a large furnace such that the plurality of blades, along with the deposited fluoro-containing polymer 306, may undergo sintering and then cooling following the conditions described above in the respective processes. In another embodiment, step 202 may be performed in continuous mode using a conveying path for transferring the blade holders 302. After the above step the conveyor may transfer the stack of blades to a belt furnace where step 204 and/or step 206 may be performed following the conditions described above in the respective processes.

Moreover, step 204 and/or step 206 may help to form a thin (e.g., approximately 20 to 80 nm, among other thicknesses) and uniform layer of fluoro-containing polymer, while at the same time having the bulk-like properties of the fluoro-containing polymer, as discussed above. For example, PTFE powder in negative pressure chamber 312 may be heated to the evaporation temperature, for example, induced by power source 308 applying a voltage. A coating of fluoro-containing polymer deposited on cutting edges 16a via evaporation may be thinner than a coating of fluoro-containing polymer applied via spraying. Due to the thinner layer of fluoro-containing polymer, the maximum temperature for melting fluoro-containing polymer may be reduced. Furthermore, the methods discussed herein may help to ensure that the fluoro-containing polymer coating is well-adhered to blade 16, for example, to cutting edge 16a. Moreover, the deposition in step 202 may be performed at less demanding and/or safer pressures, for example, approximately 10-1 torr to approximately 10-2 torr, than other evaporation processes known in the art.

Additionally, the furnace may help to control the heating and cooling, for example, gradually heating and/or cooling and/or controlling the heating and/or cooling profiles. For example, heating blades 16, with the coating of fluoro-containing polymer, to temperatures above the melting temperature of fluoro-containing polymer, and the subsequent cooling, may help to form a thin and uniform layer of fluoro-containing polymer, while maintaining the bulk-like properties, as discussed herein. The heating profile (i.e., the maximum temperature, the heating rate, the total time of the fluoro-containing polymer is heated above approximately 280 degrees, etc.) may affect the final properties of the fluoro-containing polymer coating. For example, the friction and cutting force performance of blade(s) 16 with the fluoro-containing polymer coating after sintering at approximately 330 degrees Celsius may be improved or otherwise demonstrate an improved performance compared to blade(s) 16 with the fluoro-containing polymer coating after sintering at approximately 345 degrees Celsius or at approximately 370 degrees Celsius.

Moreover, slower or more gradual cooling rates (e.g., from approximately 2 degrees Celsius per minute to approximately 5 degrees Celsius per minute) may help to yield thinner and/or more homogenous or otherwise uniform coatings of fluoro-containing polymer compared to more rapid cooling rates (e.g., above approximately 10 degrees Celsius per minute). For example, as shown in FIGS. 6A and 6B, which are optical microscope images of blades, respectively, blades treated with the same deposition process, but sintered at different temperatures may yield different properties. For example, sintering to the same maximum temperature (i.e., approximately 330 degrees Celsius), but cooling at different rates may yield different properties. Controlling the cooling stage (i.e., step 206) may affect the properties of the fluoro-containing polymer coated blade to a greater extent than the heating stage (i.e., step 204). For example, the cooling stage may affect the crystallization of fluoro-containing polymer, and the final morphology of the fluoro-containing polymer film. The morphology may affect the friction and cutting force, along with the uniformity of the film, thus affecting the shaving performance and/or user comfort during a shaving session.

In some aspects, the cooling from the maximum temperature (e.g., approximately 330 degrees Celsius) to approximately 300 degrees Celsius is the most important factor in the crystallization of fluoro-containing polymer, and the final morphology of the fluoro-containing polymer film, and thus the homogeneity and/or crystallinity, which may be observed via X-ray photoelectron spectroscopy analysis, x-ray diffraction, and/or other techniques. For example, slower cooling rates, for example, of approximately 5 degrees Celsius or slower during the cooling step, especially from the maximum temperature (e.g., approximately 330 degrees Celsius) to approximately 300 degrees Celsius, may help to provide thinner and/or more homogeneous coatings, with improved friction and cutting force performance.

The thickness and/or the frictional properties of the final fluoro-containing polymer coating on blade(s) 16, for example, on blade edge(s) 16a, may be controlled by adjusting one or more of the following parameters during the deposition step (e.g., step 202): the molecular weight of fluoro-containing polymer 306, the quantity of fluoro-containing polymer 306 within boat 304, the material of boat 304, the evaporation temperature (e.g., after applying voltage from power source 308), the pressure within negative pressure chamber 312, the duration of the evaporation step, the distance between boat 304 and blade edge(s) 16a. Moreover, the thickness and/or the frictional properties of the final fluoro-containing polymer coating on blade(s) 16, for example, on blade edge(s) 16a, may be controlled by adjusting one or more of the following parameters during the sintering step (e.g., step 204): the maximum temperature for melting fluoro-containing polymer 306, or the hold time/duration at the maximum temperature. Additionally, the thickness and/or the frictional properties of the final fluoro-containing polymer coating on blade(s) 16, for example, on blade edge(s) 16a, may be controlled by adjusting the cooling rate after melting of fluoro-containing polymer 306 (e.g., from the maximum temperature to an intermediate temperature) during the cooling step (e.g., step 206).

Blade(s) 16 with the fluoro-containing polymer coating may help to provide a comfortable and/or easy shaving experience for a user. The fluoro-containing polymer coating may help to reduce the required force, for example, to cut hairs. The fluoro-containing polymer, for example, because of the bulk-like properties, may help to reduce friction forces, for example, between blade(s) 16 and the user's face, while also reducing the required force to cut hair. In some aspects, blade(s) 16 with the fluoro-containing polymer coating as discussed herein may exhibit similar properties as a blade with sprayed PTFE, for example, require exhibit similar cutting and friction forces. However, blade(s) 16 with the fluoro-containing polymer coating as discussed herein may include a thickness of PTFE less than approximately 400 nm, for example, less than approximately 80 nm, with the fluoro-containing polymer coating being uniform, homogenous, etc. As a result, blade(s) 16 with the fluoro-containing polymer coating as discussed herein may provide an improved shaving performance with low cutting and friction forces, for example, improved fluidity. Moreover, in some aspects, using existing special grade PTFE (LW 2120) does not require a new material, but still helps to obtain the above-discussed properties of blade(s) 16 with the fluoro-containing polymer coating.

It should be appreciated that in the above description of exemplary embodiments of the disclosure, various features of the disclosure are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed disclosure requires more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this disclosure.

Furthermore, while some embodiments described herein include some but not other features included in other embodiments, combinations of features of different embodiments are meant to be within the scope of the disclosure, and form different embodiments, as would be understood by those skilled in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the disclosure.

In the description provided herein, numerous specific details are set forth. However, it is understood that embodiments of the disclosure may be practiced without these specific details. In other instances, well-known methods, structures, and techniques have not been shown in detail in order not to obscure an understanding of this description.

While there has been described what are believed to be the preferred embodiments of the disclosure, those skilled in the art will recognize that other and further modifications may be made thereto without departing from the spirit of the disclosure, and it is intended to claim all such changes and modifications as falling within the scope of the disclosure. For example, any formulas given above are merely representative of procedures that may be used. Functionality may be added or deleted from the block diagrams and operations may be interchanged among functional blocks. Steps may be added or deleted to methods described within the scope of the present disclosure.

The above disclosed subject matter is to be considered illustrative, and not restrictive, and the appended claims are intended to cover all such modifications, enhancements, and other implementations, which fall within the true spirit and scope of the present disclosure. Thus, to the maximum extent allowed by law, the scope of the present disclosure is to be determined by the broadest permissible interpretation of the following claims and their equivalents and shall not be restricted or limited by the foregoing detailed description. While various implementations of the disclosure have been described, it will be apparent to those of ordinary skill in the art that many more implementations and implementations are possible within the scope of the disclosure. Accordingly, the disclosure is not to be restricted except in light of the attached claims and their equivalents.

As is evident from the figures, text, and examples presented above, a variety of embodiments may be contemplated as follows:

1. A method of forming a coating on a blade for a shaver, the method comprising:
a first step of evaporating a portion of a supply of a lubricating coating material in a negative pressure chamber, wherein the blade is positioned in the negative pressure chamber adjacent to the supply of the lubricating coating material such that the portion of the lubricating coating material evaporates from the supply and coats the blade;
a second step, performed after the first step, of sintering the portion of the lubricating coating material coating the blade by heating the blade to a temperature above the melting temperature of the lubricating coating material; and
a third step, performed after the second step, of cooling the blade after sintering to a room temperature.

2. The method of claim 1, wherein evaporating the supply of the lubricating coating material includes heating the supply of the lubricating coating material by applying a voltage to an evaporation boat containing the supply of the lubricating coating material.

3. The method of claim 1 or claim 2, wherein evaporating the supply of the lubricating coating material includes heating the supply of the lubricating coating material for about 5 minutes to about 30 minutes.

4. The method of any one of claims 1-3, wherein evaporating includes heating the boat to a temperature of about 200 degrees Celsius to about 400 degrees Celsius, specifically 330 degrees Celsius to about 380 degrees Celsius.

5. The method of any one of claims 1-4, wherein sintering includes heating the blade to a temperature of about 200 degrees Celsius to about 400 degrees Celsius, specifically about 330 degrees Celsius to about 380 degrees Celsius.

6. The method of claim 5, wherein sintering the blade to a temperature includes:
heating from a room temperature to an intermediate temperature of about 200 degrees to 300 degrees Celsius at a rate of about 40 to about 60 degrees Celsius per minute, and
heating from the intermediate temperature to a maximum temperature at a rate of about 5 to about 20 degrees Celsius per minute, specifically to about 10 degrees Celsius per minute.

7. The method of any one of claim 5 or 6, wherein sintering occurs in 1-40 degrees Celsius above the melting temperature, more specifically in 10-30 degrees Celsius above the melting temperature.

8. The method of any of claims 4-7, wherein cooling the blade includes:
cooling from the maximum temperature to the intermediate temperature of about 200 degrees to 300 degrees Celsius at a rate of about 2 to about 10 degrees Celsius per minute, specifically to about 5 degrees Celsius per minute, and then
cooling from about the intermediate temperature of about 200 degrees to 300 degrees Celsius to a room temperature at a rate of about 20 to about 40 degrees Celsius per minute.

9. The method of any one of the preceding claims, wherein the blade is one of a plurality of blades, and wherein each of the plurality of blades is mounted on a blade holder.

10. The method of claim 9, wherein the blade holder is positioned from about 3 to about 10 cm above the supply of the lubricating coating material in the negative pressure chamber.

11. The method of any one of the preceding claims, wherein evaporating the supply of the lubricating coating material is performed at about 10-1 torr to about 10-6 torr.

12. The method of any one of the preceding claims, wherein sintering and cooling are performed in a furnace.

13. The method of any one of the preceding claims, wherein the lubricating coating material is a polymeric material, more specifically a non-metallic polymeric material.

14. The method of any one of the preceding claims, wherein the lubricating coating material is any fluoropolymer/fluoro-containing polymer, specifically polytetrafluoroethylene.

15. The method of any one of the preceding claims, wherein after cooling, the blade includes a coating of the lubricating coating material having a thickness of about 10 nm to about 400 nm, specifically 20 nm to about 100 nm.

16. The method of any one of the preceding claims, wherein the supply of the lubricating coating material in the negative pressure chamber includes a powder of the lubricating coating material.

17. The method of any one of the preceding claims, wherein after cooling, the blade includes a coating having a F/C ratio greater than about 1.7.

18. The method of any one of the preceding claims, wherein after cooling, the blade includes a coating having a CF2 content greater than about 60%.

19. A blade formed using the method of any one of the preceding claims.

20. A shaving assembly, comprising:
a handle; and
a cartridge including one or more blades as claimed in claim 19.

1. A method of forming a coating on a blade for a shaver, the method comprising:
a first step of evaporating a portion of a supply of a lubricating coating material in a negative pressure chamber, wherein the blade is positioned in the negative pressure chamber adjacent to the supply of the lubricating coating material such that the portion of the lubricating coating material evaporates from the supply and coats the blade;
a second step, performed after the first step, of sintering the portion of the lubricating coating material coating the blade by heating the blade to a temperature above the melting temperature of the lubricating coating material; and
a third step, performed after the second step, of cooling the blade after sintering to a room temperature.

2. The method of claim 1, wherein evaporating the supply of the lubricating coating material includes heating the supply of the lubricating coating material by applying a voltage to an evaporation boat containing the supply of the lubricating coating material.

3. The method of claim 1, wherein evaporating the supply of the lubricating coating material includes heating the supply of the lubricating coating material for about 5 minutes to about 30 minutes.

4. The method of claim 1, wherein evaporating includes heating the boat to a temperature of about 200 degrees Celsius to about 400 degrees Celsius.

5. The method of claim 1, wherein sintering includes heating the blade to a temperature of about 200 degrees Celsius to about 400 degrees Celsius.

6. The method of claim 5, wherein sintering the blade to a temperature includes:
heating from a room temperature to an intermediate temperature of about 200 degrees to 300 degrees Celsius at a rate of about 40 to about 60 degrees Celsius per minute, and
heating from the intermediate temperature to a maximum temperature at a rate of about 5 to about 20 degrees Celsius per minute.

7. The method of claim 5, wherein sintering occurs in 1-40 degrees Celsius above the melting temperature.

8. The method of claim 4, wherein cooling the blade includes:
cooling from the maximum temperature to the intermediate temperature of about 200 degrees to 300 degrees Celsius at a rate of about 2 to about 10 degrees Celsius per minute, and then
cooling from about the intermediate temperature of about 200 degrees to 300 degrees Celsius to a room temperature at a rate of about 20 to about 40 degrees Celsius per minute.

9. The method of claim 1, wherein the blade is one of a plurality of blades, and wherein each of the plurality of blades is mounted on a blade holder.

10. The method of claim 9, wherein the blade holder is positioned from about 3 to about 10 cm above the supply of the lubricating coating material in the negative pressure chamber.

11. The method of claim 1, wherein evaporating the supply of the lubricating coating material is performed at about 10-1 torr to about 10-6 torr.

12. The method of claim 1, wherein sintering and cooling are performed in a furnace.

13. The method of claim 1, wherein the lubricating coating material is a polymeric material.

14. The method of claim 1, wherein the lubricating coating material is any fluoropolymer/fluoro-containing polymer.

15. The method of claim 1, wherein after cooling, the blade includes a coating of the lubricating coating material having a thickness of about 10 nm to about 400 nm.

16. The method of claim 1, wherein the supply of the lubricating coating material in the negative pressure chamber includes a powder of the lubricating coating material.

17. The method of claim 1, wherein after cooling, the blade includes a coating having a F/C ratio greater than about 1.7.

18. The method of claim 1, wherein after cooling, the blade includes a coating having a CF2 content greater than about 60%.

19. A blade formed using the method of claim 1.

20. A shaving assembly, comprising:
a handle; and
a cartridge including one or more blades as claimed in claim 19.
